(19) United States
(12) Patent Application Publication
(10) Pub. No.: US 2012/0032195 A1
(43) Pub. Date: Feb. 9, 2012

(54) DISPLAY PANEL

(76) Inventors: Wei-Long Li, Taoyuan County (TW); Chien-Chih Jen, Taoyuan County (TW); Kuang-Kuei Wang, Taoyuan County (TW)

(21) Appl. No.: 12/967,077

(22) Filed: Dec. 14, 2010

(30) Foreign Application Priority Data
Aug. 5, 2010 (TW) 099214983

(51) Int. Cl. H01L 33/08

(52) U.S. Cl. 257/88; 257/E33.053

(57) ABSTRACT

A display panel includes a substrate and a plurality of pixel units. Each pixel unit includes a first thin film transistor and a second thin film transistor. The first thin film transistor includes a first gate electrode electrically connected to a fist gate line, a first source electrode electrically connected to a data line, and a first drain electrode electrically connected to a first pixel electrode. The second thin film transistor includes a second gate electrode electrically connected to a second gate line, a second source electrode electrically connected to the data line, and a second drain electrode electrically connected to a second pixel electrode. The first drain electrode extends along a first direction to overlap the first gate electrode, and the second drain electrode extends along the first direction to overlap the second gate electrode.

### BACKGROUND OF THE INVENTION

1. Field of the Invention

The present invention relates to a display panel, and more particularly, to a display panel capable of reducing variation of feed through voltage between adjacent pixels.

2. Description of the Prior Art

Based on different driving modes, display panels can be mainly classified as: single-gate type display panels and dual-gate type display panels. Under the same resolution, the number of gate lines of a dual-gate type display panel is doubled and the number of data lines of a dual-gate type display panel is reduced by half compared to that of a single-gate type display panel. Thus, more gate driving chips and less source driving chips are required for a dual-gate type display panel. The cost and power consumption of gate driving chips is lower than those of the source driving chips, and therefore the dual-gate type display panel is beneficial for its reduced cost and power consumption.

Please refer to FIG. 1A, which schematically illustrates a conventional dual-gate type display panel. As shown in FIG. 1A, a data line S1, a first gate line G1, and a second gate line G2 are positioned on a substrate 100. A first thin film transistor (TFT) T1 is located on the left side of the data line S1, and a second TFT T2 is located on the right side of the data line S1, where the first TFT T1 and the second TFT T2 share the data line S1. Moreover, the first TFT T1 and the second TFT T2 have the same gate-drain capacitance. More precisely, the overlapping area between the first gate electrode 11 and the first drain electrode 13 of the first TFT T1 is the same as that between the second gate electrode 21 and the second drain electrode 23 of the second TFT T2, as shown in FIG. 1A, where each overlapping area has a width of a and a length of b.

However, when unexpected process deviation causes misalignment of respective layers, the first TFT T1 and the second TFT T2 will have different gate-drain capacitances. Please refer to FIG. 1B, which schematically illustrates a conventional dual-gate type display panel with misalignment along Y direction. As shown in FIG. 1B, the first drain electrode 13 of the first TFT T1 and the second drain electrode 23 of the second TFT T2 extend toward different directions to overlap the first gate electrode 11 and the second gate electrode 21 respectively, and thus, when misalignment along Y direction occurs in the processes of the formation of gate electrodes and drain electrodes in different layers, the overlapping area between the first gate electrode 11 and the first drain electrode 13 of the first TFT T1 will become larger than that between the second gate electrode 21 and the second drain electrode 23 of the second TFT T2. More precisely, the overlapping area between the first gate electrode 11 and the first drain electrode 13 of the first TFT T1 has a width of a and a length of b+u; and the overlapping area between the second gate electrode 21 and the second drain electrode 23 of the second TFT T2 has a width of a and a length of b−u. Accordingly, the difference of the gate-drain capacitances between the first TFT T1 and the second TFT T2 would cause two adjacent pixel units to have different feed through voltages, and further lead to flicker problem of display panels.

### SUMMARY OF THE INVENTION

It is therefore one of the objectives of the present invention to provide a display panel capable of resolving flicker problem of the conventional display panel.

According to an embodiment of the present invention, a display panel includes a substrate, and a plurality of pixel units located on the substrate. Each of the pixel units includes a first gate line, a second gate line, a data line, a first pixel and a second pixel. The first pixel is located on one side of the data line and between the first gate line and the second gate line. Moreover, the first pixel includes a first pixel electrode and a first TFT, and the first TFT includes a first gate electrode electrically connected to the first gate line, a first source electrode electrically connected to the data line, and a first drain electrode electrically connected to the first pixel electrode. In addition, the second pixel is located on the other side of the data line and between the first gate line and the second gate line. Moreover, the second pixel includes a second pixel electrode and a second TFT. The second TFT includes a second gate electrode electrically connected to the second gate line, a second source electrode electrically connected to the data line, and a second drain electrode electrically connected to the second pixel electrode. The first drain electrode extends along a first direction toward the first gate electrode to overlap the first gate electrode, and the second drain electrode also extends along the first direction toward the second gate electrode to overlap the second gate electrode.

In each of the pixel units of the display panel of the present invention, the extension direction of the first drain electrode, which overlaps the first gate electrode, is identical to that of the second drain electrode, which overlaps the second gate electrode. Accordingly, even when misalignment of respective layers due to process variation occurs, the overlapping area between the first gate electrode and the first drain electrode of the first TFT will be maintained the same as that between the second gate electrode and the second drain electrode of the second TFT. Therefore, the feed through voltages of any two adjacent pixels could be maintained equal, and the flicker problem of display panels can be diminished.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram illustrating a conventional dual-gate type display panel.

FIG. 1B is a schematic diagram illustrating a dual-gate type display panel with misalignment along Y direction.

FIG. 2 is a schematic diagram illustrating a display panel of a first preferred embodiment of the present invention.

FIG. 3A is a schematic diagram illustrating a first TFT of the first preferred embodiment of the present invention.

FIG. 3B is a schematic diagram illustrating a first TFT according to a configuration of the present invention.

FIG. 4 is a schematic diagram illustrating a first TFT according to another configuration of the present invention.

FIG. 5 is a schematic diagram illustrating a first TFT according to still another configuration of the present invention.

FIG. 6 is a schematic diagram illustrating a black matrix corresponding to a pixel unit of the present invention.

FIG. 7 is a schematic diagram illustrating a display panel of a second preferred embodiment of the present invention.

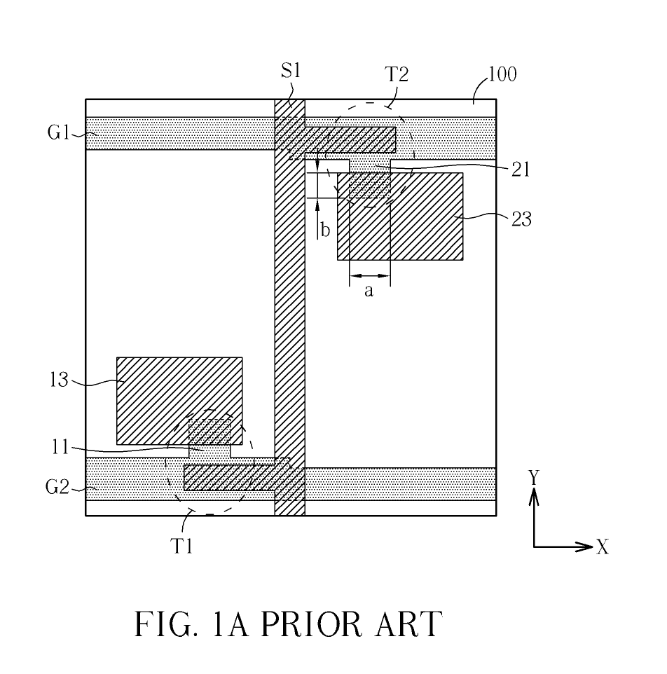

### DETAILED DESCRIPTION

Certain terms are used throughout the following description and claims to refer to particular components. As one skilled in the art will appreciate, manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ” The terms “electrically connect” and “electrically connected” are intended to mean either an indirect or a direct electrical connection. Thus, if a first device electrically connects a second device, that connection may be through a direct electrical connection, or through an indirect electrical connection via other devices and connections. It is noted that all figures are not to scale.

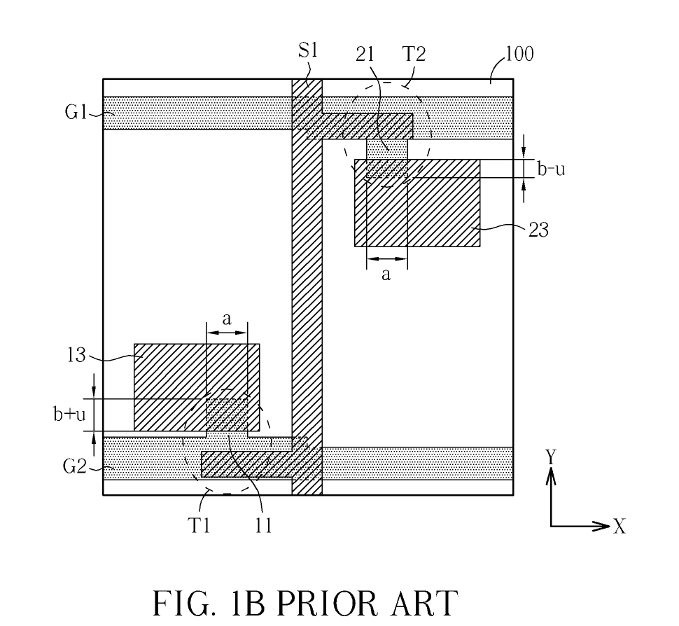

Please refer to FIG. 2, which schematically illustrates a display panel of a first preferred embodiment of the present invention. For the sake of clear illustration, only a part of components, instead of all components, are illustrated in FIG. 2. As shown in FIG. 2, the display panel of the present invention includes a substrate 200 and a plurality of pixel units located on the substrate 200. Also, only four pixel units arranged in a matrix are drawn in FIG. 2. Each pixel unit includes a first gate line G1, a second gate line G2, a data line S1, a first pixel, and a second pixel. The first pixel is located on one side (e.g. the left side in FIG. 2) of the data line S1 and positioned between the first gate line G1 and the second gate line G2. The first pixel further includes a first pixel electrode P1 and a first TFT T1. The first TFT T1 includes a first gate electrode 11 electrically connected to the first gate line G1, a first source electrode 12 electrically connected to the data line S1, and a first drain electrode 13 electrically connected to the first pixel electrode P1. Additionally, the first TFT T1 further includes a semiconductor layer (not shown) positioned between the first gate electrode 11 and the first source electrode 12, and between the first gate electrode 11 and the first drain electrode 13. More precisely, the first source electrode 12 and the first drain electrode 13 could be made of the same patterned conductive layer, the first gate electrode 11 could be made of another patterned conductive layer, and the semiconductor layer could be positioned between the two patterned conductive layers.

In addition, as shown in FIG. 2, the second pixel is located on the other side (e.g. the right side in FIG. 2) of the data line S1 and positioned between the first gate line G1 and the second gate line G2. The second pixel includes a second pixel electrode P2 and a second TFT T2. The second TFT T2 includes a second gate electrode 21 electrically connected to the second gate line G2, a second source electrode 22 electrically connected to the data line S1, and a second drain electrode 23 electrically connected to the second pixel electrode P2. The second TFT T2 further includes a semiconductor layer (not shown) positioned between the second gate electrode 21 and the second source electrode 22, and between the second gate electrode 21 and the second drain electrode 23. In the preferred embodiment, the first drain electrode 13 extends along a first direction D1 toward the first gate electrode 11 to overlap the first gate electrode 11, and the second drain electrode 23 also extends along the first direction D1 toward the second gate electrode 21 to overlap the second gate electrode 21. In addition, the display panel of the first preferred embodiment further includes at least one photo-spacer 30, which is located between at least two pixel units of the plurality of pixel units, to maintain the consistency of gap between the substrate 200 and the other corresponding substrate (not shown). Accordingly, drawbacks such as image blur duo to the inconsistency of gap between two substrates can be prevented. It is appreciated that the photo-spacer 30 as shown in FIG. 2 is located on the first gate line G1 and the second gate line G2, but the location of the photo-spacer 30 is not limited. The location of the photo-spacer 30 may be modified based on the designer's discretion. For example, the photo-spacer 30 could be positioned on other components such as the semiconductor layer, the source electrode or the drain electrode.

In each of the pixel units of the first preferred embodiment, the overlapping area between the first drain electrode 13 and the first gate electrode 11 is the same as that between the second drain electrode 23 and the second gate electrode 21, and thus, the first TFT T1 and the second TFT T2 have the same gate-drain capacitance. Moreover, in each pixel unit, the extension direction of the first drain electrode 13 which overlaps the first gate electrode 11 is identical to that of the second drain electrode 23 which overlaps the second gate electrode 21. As a result, even when misalignment of respective layers due to process variation occurs in either horizontal or vertical direction, the variation of the overlapping area between the first drain electrode 13 and the first gate electrode 11 of the first TFT T1 is the same as that between the second drain electrode 23 and the second gate electrode 21 of the TFT T2. More precisely, the feed through voltages of adjacent pixels of the display panel of the present invention are not affected by misalignment of respective layers in any directions. As a result, the display panel of the present invention is able to solve flicker problem of the prior art duo to the variation of feed through voltages between adjacent pixels.

In comparison with the conventional design, the display panel of the present invention has a lower gate-drain capacitance. More specifically, the pixel of the conventional display panel has two overlapping areas between the gate electrode and the drain electrode. When process deviation occurs, one of the overlapping areas will increase while the other overlapping area will decrease, and the increase area will be equal to the reduced area. However, the conventional design would lead to increase of the area of TFTs, thus the aperture ratio would be reduced. Also, the gate-drain capacitance of a single pixel would be increased consequentially. On the other hand, the TFTs of the display panel of the present invention occupy smaller area, thus the aperture ratio would be increased. In addition, the display panel of the present invention has a lower gate-drain capacitance, thereby reducing feed through voltages and further promoting display quality.

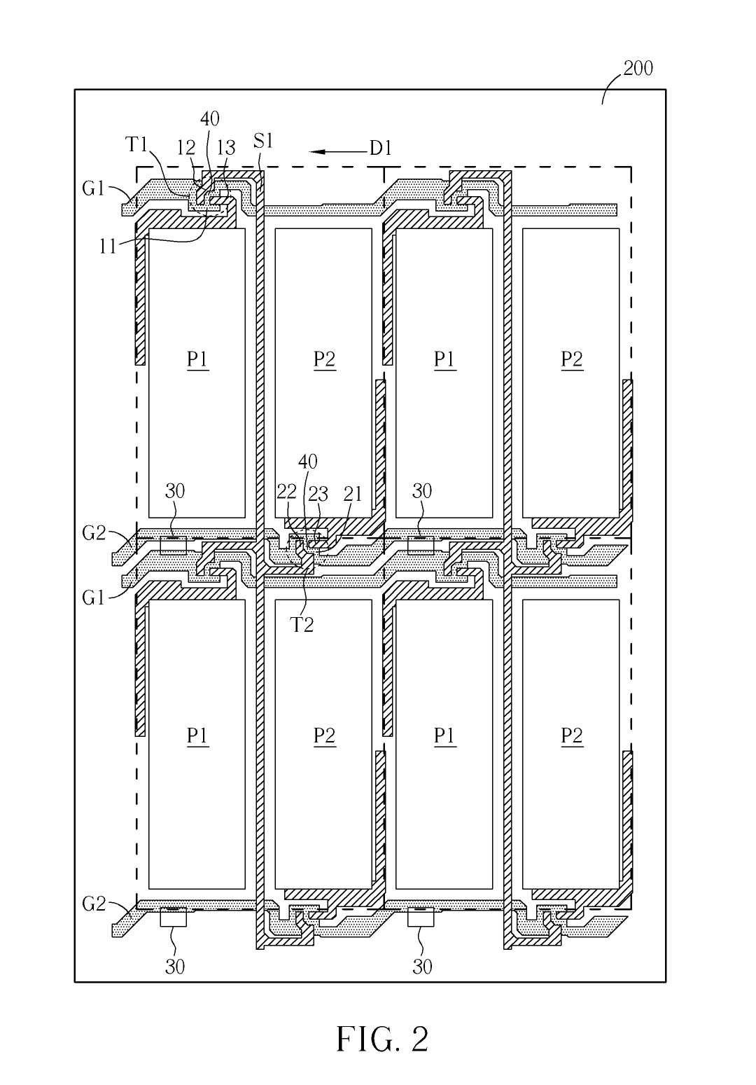

To clearly illustrate the configurations of TFTs of the display panel of the present invention, the following descriptions focus on the first TFT T1 of the first preferred embodiment. Please refer to FIG. 3A, which schematically illustrates a first TFT of the first preferred embodiment. As shown in FIG. 3A, a channel region 40 is positioned between the first source electrode 12 and the first drain electrode 13. When viewing from top, the channel region 40 has an “L” shape. Similarly, as shown in FIG. 2, the second TFT T2 is substantially the same as the first TFT T1, and thus a channel region 40 is also positioned between the second source electrode 22 and the second drain electrode 23, and the channel region 40 has an “L” shape as well. In the first preferred embodiment, the first direction D1 is substantially parallel to the extension direction of the first gate line G1, but is not limited thereto. Please refer to FIG. 3B, which schematically illustrates a first TFT according to a configuration of the present invention. As shown in FIG. 3B, the first direction D1 and the extension direction D2 of the first gate line G1 has an included angle A, and the included angle A is larger than zero degree and less than 180 degrees. More precisely, as long as the extension direction of the first drain electrode 13 which overlaps the first gate electrode 11 is identical to that of the second drain electrode 23 which overlaps the second gate electrode 21, the feed through voltages of adjacent pixels of the present invention could be maintained equal.

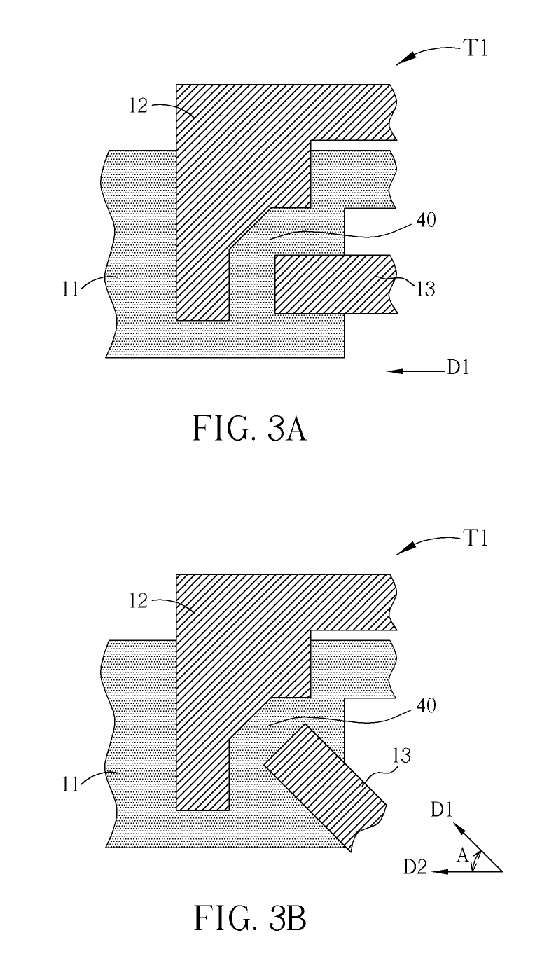

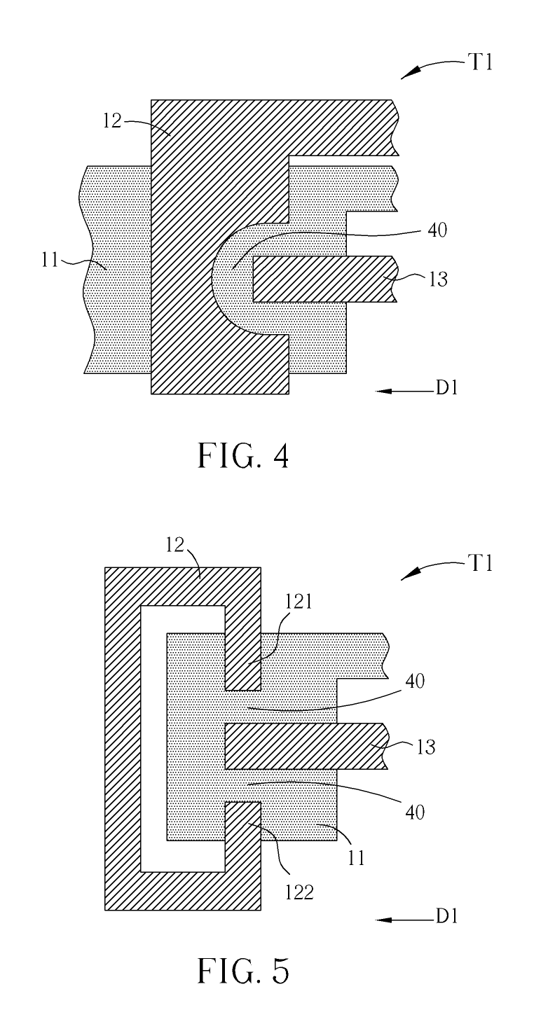

Additionally, the TFT of the display panel of the present invention has other configurations. Please refer to FIG. 4, which schematically illustrates a first TFT T1 according to another configuration of the present invention. As shown in FIG. 4, a channel region 40 is positioned between the first source electrode 12 and the first drain electrode 13. When viewing from top, the channel region 40 has a “U” shape, instead of the “L” shape shown in FIG. 3A. Please refer to FIG. 5, which schematically illustrates a first TFT T1 according to still another configuration of the present invention. As shown on FIG. 5, the first source electrode 12 includes two extension terminals 121, 122 overlapping the first gate electrode 11 respectively, and the first drain electrode 13 is located between the two extension terminals 121, 122 of the first source electrode 12. The configurations of the TFT T1 can be also applied to the second TFT T2, and thus is not redundantly described. In addition, the channel regions of the first TFT T1 and the second TFT T2 of each pixel unit in a display panel preferably have the same shape. Accordingly, the feed through voltages of adjacent pixels could be maintained the same.

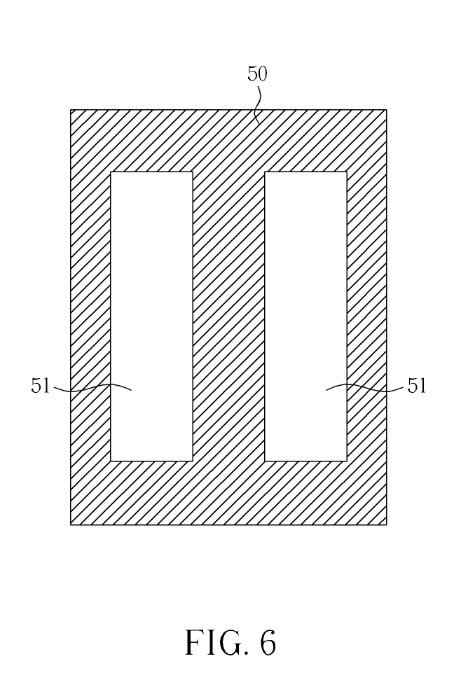

Please refer to FIG. 6, which schematically illustrates a black matrix corresponding to a pixel unit of the present invention. As shown in FIG. 6, the display panel of the present invention further includes a black matrix 50. It is appreciated that FIG. 6 only illustrates a unit of the black matrix 50 corresponding to a pixel unit of the present invention, and the black matrix 50 has a plurality of units corresponding to a plurality of pixel units. Moreover, the black matrix 50 can be positioned on either the substrate 200 or the other corresponding substrate (not shown). In the present invention, the black matrix 50 has a plurality of non-transparent mesh patterns, which include a plurality of transparent regions 51. The transparent regions 51 substantially correspond to the first pixel electrodes P1 and the second pixel electrodes P2 respectively. Also, the intervals between adjacent transparent regions 51 are substantially the same. With the arrangement of the black matrix 50, the display panel of the present invention is able to have a better display performance, and to lessen the appearance of vertical or horizontal stripes.

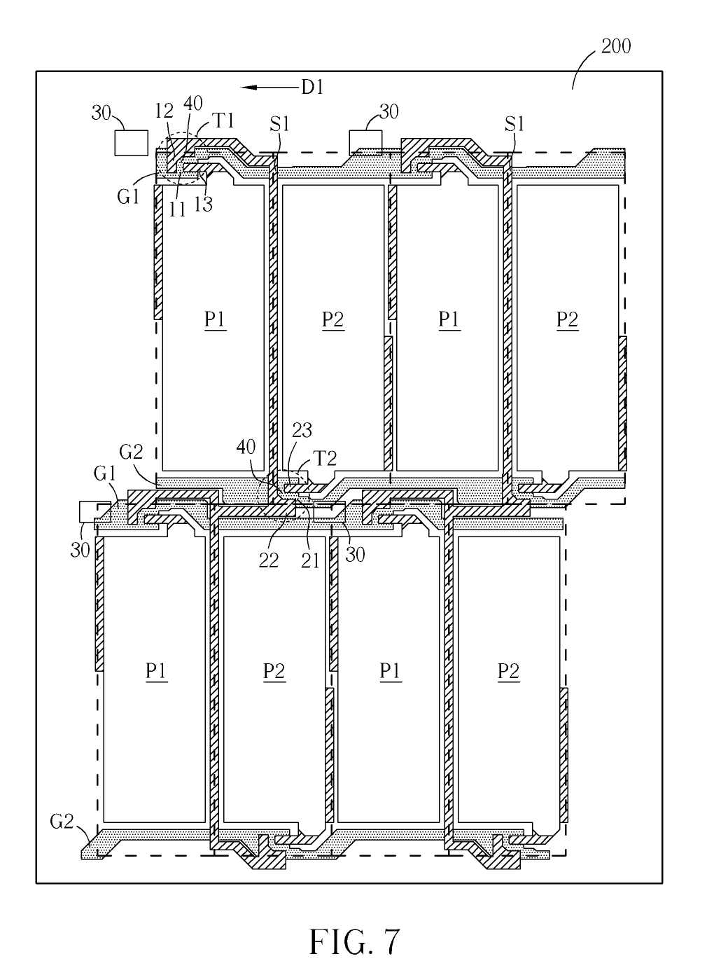

Please refer to FIG. 7, which schematically illustrates a display panel of a second preferred embodiment of the present invention. The following descriptions only focus on the differences between the first preferred embodiment and the second preferred embodiment, and thus the similar aspects of the first preferred embodiment and the second preferred embodiment are not redundantly described. In addition, identical components are denoted by identical numerals. As shown in FIG. 7, the pixel units are arranged alternately, where the first pixel electrode P1, the second pixel electrode P2 of each pixel unit and another pixel electrode P1 of one of the adjacent pixel units are arranged as a delta pattern. Accordingly, the alternate arrangement of the pixel units makes it possible to dispose the pixel units on the display panel more effectively, and to reduce the area of the non-display region. Consequently, the aperture ratio is improved.

To sum up, in each pixel unit of the display panel of the present invention, the extension direction of the first drain electrode which overlaps the first gate electrode is identical to that of the second drain electrode which overlaps the second gate electrode. Accordingly, when misalignment of respective layers due to process deviation occurs, the overlapping area between the first gate electrode and the first drain electrode of the first TFT will be kept the same as that between the second gate electrode and the second drain electrode of the second TFT. Therefore, the feed through voltages of adjacent pixels of the display panel could remain the same, and thus the flicker problem of the display panel could be diminished. Moreover, the TFTs of the display panel of the present invention occupy smaller area, so that the aperture ratio can be improved consequently. In addition, the TFTs of the display panel of the present invention have lower gate-drain capacitance, which is able to reduce the feed through voltage and to further enhance the display quality.

Those skilled in the art will readily observe that numerous modifications and alterations of the device and method may be made while retaining the teachings of the invention.

What is claimed is:

1. A display panel, comprising:
a substrate; and
a plurality of pixel units positioned on the substrate, wherein each of the pixel units comprises:
a first gate line, a second gate line and a data line;
a first pixel, positioned on one side of the date line and between the first gate line and the second gate line, wherein the first pixel comprises:
a first pixel electrode; and
a first TFT, comprising:
a first gate electrode, electrically connected to the first gate line;
a first source electrode, electrically connected to the data line; and
a first drain electrode, electrically connected to the first pixel electrode; and
a second pixel, positioned on the other side of the date line and between the first gate line and the second gate line, wherein the second pixel comprises:
a second pixel electrode; and
a second TFT, comprising:
a second gate electrode, electrically connected to the second gate line;
a second source electrode, electrically connected to the data line; and
a second drain electrode, electrically connected to the second pixel electrode;
wherein the first drain electrode extends along a first direction toward the first gate electrode to overlap the first gate electrode, and the second drain electrode extends along the first direction toward the second gate electrode to overlap the second gate electrode.

2. The display panel of claim 1, wherein the first direction is substantially parallel to an extension direction of the first gate line.

3. The display panel of claim 1, wherein an included angle of the first direction and the extension direction of the first gate line is larger than zero degree and less than 180 degrees.

4. The display panel of claim 1, wherein a channel region is located between the first source electrode and the first drain electrode, and a channel region is located between the second source electrode and the second drain electrode.

5. The display panel of claim 4, wherein the channel region is formed as an “L” shape.

6. The display panel of claim 4, wherein the channel region is formed as a “U” shape.

7. The display panel of claim 1, wherein the first source electrode comprises two extension terminals respectively overlapping the first gate electrode, and the first drain electrode is located between the two extension terminals of the first source electrode.

8. The display panel of claim 1, wherein the pixel units are arranged in a matrix.

9. The display panel of claim 1, wherein the pixel units are dislocated such that the first pixel electrode and the second pixel electrode of one of the pixel units, and the first pixel electrode of another adjacent pixel unit are arranged as a triangle.

10. The display panel of claim 1, further comprising a black matrix, wherein the black matrix comprises a plurality of non-transparent mesh patterns, wherein the non-transparent mesh pattern comprises a plurality of transparent regions substantially corresponding to the first electrode and the second electrode of each pixel unit, and a distance between two adjacent transparent regions is equal.
